(19) United States
(12) Patent Application Publication
(10) Pub. No.: US 2007/0292776 A1
(43) Pub. Date: Dec. 20, 2007

(54) OVERLAY VERNIER KEY AND METHOD FOR FORMING CONTACT HOLES OF SEMICONDUCTOR DEVICE USING THE SAME

(75) Inventors: Byeong Ho Cho, Icheon-si (KR); Yeong Bae Ahn, Cheongju-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-shi (KR)

(21) Appl. No.: 11/759,199

(22) Filed: Jun. 6, 2007

(30) Foreign Application Priority Data
Jun. 20, 2006 (KR) 10-2006-0055353
Dec. 28, 2006 (KR) 10-2006-0137234

(51) Int. Cl. G03F 9/00

(52) U.S. Cl. 430/22

(57) ABSTRACT

A substrate includes an overlay vernier key structure that includes an outer pattern formed over one layer over a semiconductor substrate, as a reference for an overlay measurement, and an inner pattern comprising a cluster of vernier patterns formed over another layer. The vernier patterns have a dimension and a pitch substantially equal to a dimension and a pitch of contact hole patterns formed to constitute a circuitry

### CROSS-REFERENCES TO RELATED APPLICATIONS

The present application claims priorities to Korean patent application number 10-2006-0055353 and 10-2006-0137234, filed on Jun. 20, 2006 and Dec. 28, 2006 respectively, which are incorporated by reference in its entirety.

### BACKGROUND OF THE INVENTION

The present invention relates to a method of manufacturing a semiconductor device, and more particularly, to method of forming an overlay vernier key which reduces the alignment error between two layers.

Recently, the demand for semiconductor devices with micro patterns has been increased due to a great increase in the degree of integration. With the patterning of a micro pattern for a semiconductor device, it has become very important to detect and control the alignment error between two layers. When a pattern having a micro critical dimension (CD) of about 100 nm (e.g., a contact hole) is formed on a wafer by a photolithography process, it is required to precisely control the alignment between the contact hole and the contact plug pad, using an overlay vernier key structure.

As shown in FIG. 1, such an overlay vernier key structure includes a box-type outer pattern 11 and an inner pattern 15. The outer pattern 11 is formed on a lower layer and the inner pattern 15 is formed on an upper layer and the relative position of these two patterns determines the alignment accuracy of the two layers. The position of the inner pattern 15 relative to the outer pattern 11 is detected using overlay measuring equipment, for example to detect the alignment of a contact hole with respect to a lower pattern. However, the inner pattern 15 (or outer pattern 11) of the overlay vernier key structure has a critical dimension (CD) that is much larger than the patterns (e.g., a contact hole) formed on a wafer.

In a memory device such as a Dynamic Random Access Memory (DRAM), an overlay vernier key structure is formed in a scribe lane region with a relatively large critical dimension (e.g., 10 μm). However, contact hole patterns, such as slit type contact holes, which are arranged in a peripheral region, may have a small critical dimension, e.g., 1/100 of the overlay vernier key. The critical dimensions of the patterns formed in the peripheral region are also reduced when the degree of integration of the semiconductor device increases.

Thus, since the size of the overlay vernier key patterns is large when compared to those of circuitry patterns (e.g., contact hole patterns) there is difficulty in controlling the alignment, based on the overlay vernier key structure measurement.

Referring to FIG. 2, patterns 26 and 28 on a photomask 25 are transferred to a wafer 21 mounted to a stage, through a light exposure process in which light 30 emitted by a light source is focused on the wafer 21 by a lens system 23 through the photomask 25.

In the light exposure process, due to a pattern size and shape difference an optical path deviation may occur between an first optical path of a first incident light 36, which transfers an image of the pattern 26 (e.g., a contact hole mask pattern) and an second optical path of a second incident light 38, which transfers an image of the pattern 28 (e.g., an overlay key mask pattern 28). Such an optical path deviation may be caused by lens aberrations included in the lens system 23. The optical path deviation caused by the lens aberrations may cause serious problems associated with the measurement of overlay and the correction of alignment based on the results of the measurement.

For example, due to an optical path deviation caused by a lens aberration, a pattern shift may occur between the contact hole pattern and the overlay key pattern. Such a pattern shift causes an overlay misalignment. This overlay misalignment is detected with a measurement carried out for an overlay key structure. That is, the pattern shift is measured by the relative position of the inner pattern 15 in the overlay key structure (FIG. 1) from the outer pattern 11. In order to compensate for the measured pattern shift, the degree of a light exposure alignment is corrected. For example, in a exposure tool, a wafer is re-aligned or position shift to compensate the detected amount of the overlay pattern shift. Accordingly, the degree of correction for an exposure alignment depends on the measurement of the pattern shift by the overlay key structure.

In a re-alignment process for correcting the overlay, the overlay misalignment is corrected with reference to the overlay key structure. In this process, however, the contact hole mask pattern 26, which has a small size, involves a relatively large position shift because the alignment correction is carried out with reference to the overlay key structure, which has a relatively large size. For this reason, even when a micro alignment correction is achieved based on the overlay key structure, the pattern in the peripheral region, for example, the contact hole pattern, involves an excessively large position shift on the wafer. As a result, another unexpected undesirable pattern misalignment may occur in the peripheral region.

In order to eliminate such an alignment error, a correction for indirectly compensating for the influence of a re-alignment carried out based on the overlay key structure may be taken into consideration. This may be achieved by deriving the correlation between the re-alignment degree based on information obtained using the overlay key structure and the pattern shift in the circuitry region caused by the re-alignment degree. For this correction, however, it is necessary to use a procedure for manually measuring and calculating critical dimensions of circuitry patterns. For this reason, a lot of time and effort are required.

### BRIEF SUMMARY OF THE INVENTION

In one aspect of the present invention, an overlay vernier key comprises; an outer pattern as a reference for an overlay measurement formed, over one layer over a semiconductor substrate, and an inner pattern comprising a cluster of vernier patterns formed over another layer over the semiconductor substrate, the vernier patters has a dimension and a pitch equal to a dimension and a pitch of contact hole patterns.

Each contact hole pattern may comprise a slit type contact hole pattern having different lengths in shorter-axis and longer-axis directions, respectively. The dimension and the pitch of each vernier pattern may be equal to a dimension and a pitch of the slit type contact hole pattern in the shorter-axis direction, respectively. The slit type contact hole pattern may be arranged in a peripheral circuit region of the semiconductor substrate, to connect a bit line layer or a metal line layer formed on the another layer to the semiconductor substrate.

In another aspect of the present invention, A method for forming contact holes in a semiconductor device, comprising: forming gates and an outer pattern as a reference for an overlay measurement over a semiconductor substrate, depositing an interlayer insulating layer covering the gates and the outer pattern, forming a photoresist pattern including contact hole patterns and an inner pattern comprising a cluster of vernier patterns of a dimension and a pitch equal to a dimension and a pitch of the contact hole patterns, over the interlayer insulating layer, detecting a position of the inner pattern and a position of the outer pattern, to perform an overlay measurement and etching the interlayer insulating layer using the photoresist pattern as an etch mask, to form contact holes through the interlayer insulating layer.

In one embodiment, a substrate includes a first region and a second region. The substrate comprises a plurality of active patterns formed in the first region of the substrate. An overlay vernier key is formed in the second region and includes an outer pattern and an inner pattern, the inner pattern formed on an inner side of the outer pattern when seen from top. The outer pattern is formed over a first layer of the substrate, the outer pattern configured to be a reference for an overlay measurement. The inner pattern is formed over a second layer of the substrate, the inner pattern comprising a cluster of first vernier patterns, each first vernier pattern having a dimension and a pitch equal to a dimension and a pitch of one of the active patterns formed on the first region.

In another embodiment, a substrate includes a first region and a second region. The substrate includes a plurality of active patterns formed in the first region of the substrate. An overlay vernier key is formed in the second region and includes a first cluster pattern including a plurality of first vernier patterns, each first vernier pattern having a dimension and a pitch substantially equal to a dimension and a pitch of a first pattern type of the active patterns formed on the first region.

In yet another embodiment, the overlay vernier key further comprises a second cluster pattern provided adjacent to the first cluster pattern and including a plurality of second vernier patterns, each second vernier pattern having a dimension and a pitch substantially equal to the dimension and a pitch of a second active type of the active patterns formed on the first region. The second cluster pattern defines an area wherein the first cluster pattern is provided within the defined area. The second cluster pattern includes two horizontal portions and two vertical portions, each of the horizontal and vertical portions including a plurality of patterns.

### BRIEF DESCRIPTION OF THE DRAWINGS

FIG. 1 is a plan view schematically illustrating an overlay vernier key structure;

FIG. 2 is a schematic view for explaining the generation of a misalignment caused by an overlay vernier key structure;

FIG. 3 is a plan view schematically illustrating an overlay vernier key structure according to an embodiment of the present invention;

FIG. 4 is a graph depicting an overlay measurement signal detected in the overlay vernier key structure according to the embodiment of the present invention;

FIG. 5 is a plan view schematically illustrating a slit type contact hole to which the overlay vernier key according to the embodiment of the present invention is applied;

FIGS. 6 and 7 are sectional views illustrating a method for forming contact holes in a semiconductor device, using the overlay vernier key structure according to the embodiment of the present invention; and

FIG. 8 is a plan view schematically illustrating a modified example of the overlay vernier key structure according to the illustrated embodiment of the present invention.

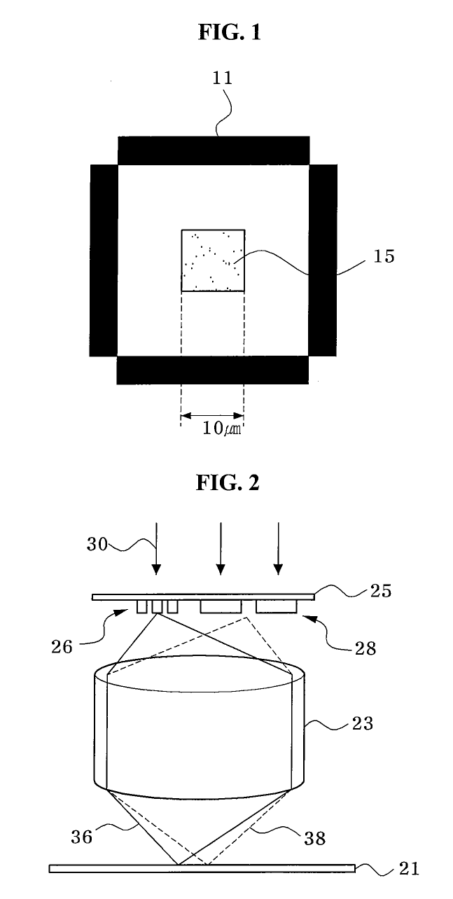

### DETAILED DESCRIPTION OF THE INVENTION

In an embodiment of the present invention, an overlay vernier key structure is proposed which can prevent or suppress the generation of an optical path deviation between a circuit pattern formed on a wafer (e.g., a pattern in a peripheral circuit region) and an optical path for each overlay vernier pattern. Because of substantially same pitch size between overlay vernier and slit contact hole pattern, an optical path deviation could be suppressed to occur. The width size or pitch size of the vernier patterns making up the overlay vernier key are set to correspond to the slit type contact hole patterns formed in the peripheral circuit region.

Such a slit type contact holes increases the contact area of the connecting contact, and thus, improves the contact resistance. The improvement in contact resistance results in an improvement in the threshold voltage Vt of a transistor connected to a line via the connecting contact. Thus, there is an improvement in the operating characteristics of the transistor. Accordingly, it is advantageous for connecting contacts arranged in the peripheral circuit region to be formed using slit type contact holes, for high integration and high-speed operation of a memory device.

The vernier patterns need to have a size substantially equal to that of the contact hole patterns. However, this would make it difficult to measure since the overlay vernier key structure needs to be a given size (e.g., at least 100 times the contact hole pattern size) in order to enable the overlay vernier key structure to be detected by the overlay measuring equipment. Accordingly, the vernier patterns are arranged to form in a cluster. The cluster (or cluster-type pattern) defines a part of an overlay vernier key structure, e.g., an inner pattern of the overlay vernier key structure having an inner pattern and an outer pattern. In the present embodiment, the cluster may define an outer pattern 100 or an inner pattern 200 (see FIG. 3). This enables the overlay measuring equipment to generate a detect signal having a sufficient and effective intensity.

In the case of a slit type contact hole pattern having a rectangular or oval planar shape with the longer-axis dimension twice the size of the shorter-axis dimension. The shorter-axis dimension of the slit type contact hole pattern is about 100 nm. In this case, each of the vernier patterns making up the overlay vernier key has a size substantially equal to the shorter-axis dimension of the slit type contact hole pattern. The vernier patterns are clustered to have a measurable overlay vernier key size, for example, a size of 10 μm.

When the slit type contact hole pattern has a size of about 100 nm, and a single vernier pattern having a size of 10 μm is used, an optical path deviation may be generated between the two patterns. As a result, there may be a pattern shift phenomenon, namely, a phenomenon that positions of image planes, to which the images of the patterns are transferred, respectively, are different from each other. Such a pattern shift phenomenon is caused by lens aberration. In an overlay measurement, such a pattern shift phenomenon is exhibited in the form of an overlay measurement error. When an overlay measurement error occurs due to lens aberrations in association with a slit type contact hole pattern, it is difficult to realize a desired slit shape because the contact hole pattern has an aspect ratio different from the aspect ratio of a square or circular contact hole pattern. Furthermore, the slit shape may be undesirably varied.

In the embodiment of the present invention, each vernier pattern 101, 201 (FIG. 3) of the cluster has a size and a pitch substantially equal to those of the slit type contact hole patterns, to compensate the optical path deviation associated with the two patterns. That is, the optical path deviation similarly occurs now in both the overly vernier pattern and the circuit layer pattern (e.g., the contact hole) This minimizes the overlay measurement error and thus misalignment.

Referring to FIG. 3, the overlay vernier key structure according to the present embodiment may have a box type key structure, similar to the conventional method. For example, the overlay vernier key structure includes an outer pattern 100 formed on a lower layer when viewing in an overlay measurement direction, and an inner pattern 200 enabling an overlay measurement based on the degree of alignment of the inner pattern 200 with the center of the outer pattern 100. The inner pattern 200 is formed on a layer different from that of the outer pattern 100. Thus, the outer pattern 100 and inner pattern 200 are used to measure the alignment between patterns formed on respective layers.

The outer pattern 100 may form the outlines or sides of the inner pattern 200. Also, the outer pattern 100 may include a plurality of first vernier patterns 101 clustered to form a first cluster at each side of the outer pattern 100. The first vernier patterns 101 making up each side of the outer pattern 100 may be repeated patterns spaced apart from one another. As shown in FIGS. 6 and 7, the first vernier patterns 101 may be formed in a scribe lane region, simultaneously with formation of gates 620 of transistors to be formed in cell regions (or a peripheral region) on a silicon (Si) semiconductor substrate 610. For simplicity of description, the following description will be given in conjunction with only one gate 620.

The spacing, size, and pitch of the first vernier patterns 101 may be set to correspond to a minimum size according to a design rule applied to the design of an associated semiconductor device, namely, a minimum design rule size. For example, the first vernier patterns 101 may have a critical dimension and a pitch substantially equal to those of the gates 620 in the cell regions. Where the semiconductor device is a memory device such as a DRAM or a flash memory device, the gates 620 may have very small critical dimensions of about 100 nm or less, (e.g., a size of about 60 nm and a pitch of about 100 nm). In this case, the first vernier patterns 101 may be designed in the form of line patterns having a length substantially equal to the length of each side of the outer pattern 100.

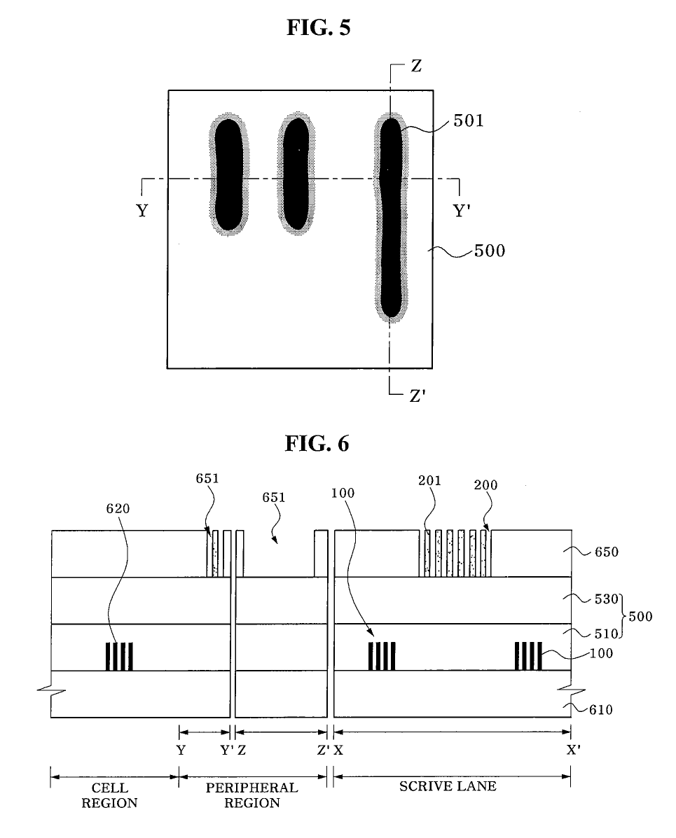

On the other hand, where the outer pattern 100 has the form of a single pattern having a size and a pitch substantially equal to those of the gates 620, in place of the first vernier patterns 101, it may be difficult to obtain a sufficient detected light intensity in an overlay measurement carried out by overlay measurement equipment. In order to obtain a sufficient detected light intensity, as shown in FIG. 4, and thus, to solve the above-described issue, the first vernier patterns 101 may be formed such that they are densely arranged to form a cluster. FIG. 4 is a graph depicting the results of an overlay measurement carried out along the line X-X′ crossing the overlay vernier key structure. Clusters of the first vernier patterns 101 respectively corresponding to respective sides of the outer pattern 100 form a square box or rim shape, to form the outer pattern 100.

Although the outer pattern 100 can be formed by the first vernier patterns 101, which are densely arranged, as described above, it may also be possible to form the outer pattern 100, using a single pattern for each side of the outer pattern 100. In this case, the single pattern has a critical dimension substantially equal to the width of the corresponding cluster. For example, single-patterns each having a critical dimension enabling a practical overlay measurement, for example, a critical dimension of about 10 μm, may be arranged in the form of a box shape, to form the outer pattern 100. In spite of this structure, in some exposure processes for gate patterning, it is possible to suppress generation of another optical path deviation caused by lens aberrations and a pattern shift phenomenon caused by the optical path deviation in association with the outer pattern 100. The first vernier pattern (100)s are formed with gate (620)s in gate (620) patterning process. So, in case of the single-10 micrometer outer pattern of the overlay key structure, another optical path deviation issues may occur between gate (620) and the single 10 micrometer outer pattern. The suppression of the pattern shift phenomenon may be effective for a more precise overlay measurement.

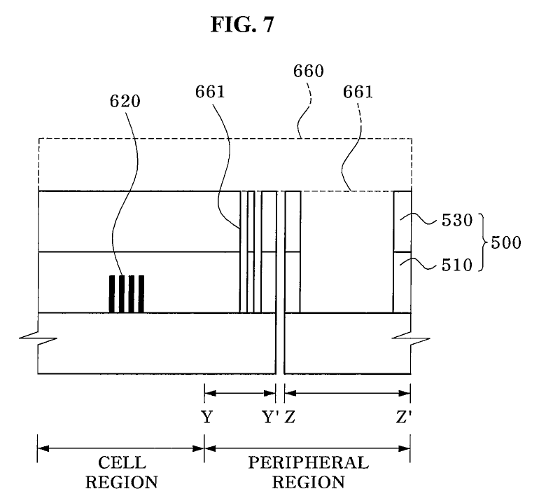

Referring to FIGS. 5 to 7, the inner pattern 200 (FIG. 3) may be formed on a photoresist layer 650 (FIG. 6), to form the overlay vernier key structure together with the outer pattern 100 arranged below the inner pattern 200, when slit type contract holes 501 (FIG. 5) are formed in an interlayer insulating layer 500 (e.g., an interlayer dielectric layer, formed as an intermediate layer for covering the cell gates 620). In this case, the interlayer dielectric layer 500 may include a first interlayer dielectric layer 510 and a second interlayer dielectric layer 530. Alternatively, the interlayer dielectric layer 500 may include the first interlayer dielectric layer 510 but not the second interlayer dielectric layer 530. For simplicity of description, the following description will be given in conjunction with only contact hole 501. When the interlayer dielectric layer 500 includes only the first interlayer dielectric layer 510, the contact hole 501 may be a contact hole for a bit line contact. On the other hand, when the interlayer dielectric layer 500 includes both the first interlayer dielectric layer 510 and the second interlayer dielectric layer 520, the contact hole 501 may be a contact hole for connecting a metal line layer. The contact hole 501 is aligned with a contact position in a peripheral region of a semiconductor substrate 610, and is formed to expose a corresponding portion of the semiconductor substrate 610 or a lower pattern, such as a contact plug, previously formed on the semiconductor substrate 610.

The slit type contact hole 501 has a longer-axis dimension and a shorter-axis dimension, so that it can secure an increased contact area, as compared to a square or circular contact hole. For formation of the slit type contact hole 501, a contact hole pattern 651 may be formed in the photoresist layer 650 such that it has a shorter-axis critical dimension of about 100 nm In the case of the slit type contact hole 501, however, it is difficult to maintain the accurate shape of the slit type contact hole 501 when a pattern shift phenomenon or a pattern deformation is generated due to lens aberrations or other factors in a light exposure process for the photoresist layer 650. Accordingly, a more precise overlay measurement and a correction for light exposure alignment may be required, in order to more reliably suppress generation of the pattern shift phenomenon.

In order to secure a more precise light exposure alignment, the inner pattern 200 is formed to have a size and a pitch capable of suppressing (or compensating) the generation of a pattern shift phenomenon or a pattern deformation due to lens aberrations or other factors in the light exposure process. As shown in FIGS. 3 and 6, the inner pattern 200 includes a plurality of second vernier patterns 201 densely and repeatedly arranged while being spaced apart from one another, to form a second cluster. The second vernier patterns 201 may be formed to have a size and a pitch substantially equal to those of cell patterns to be formed in the cell regions or circuit patterns constituting the semiconductor device, for example, the slit type contact holes 501 (FIG. 5).

As shown in FIG. 6, the inner pattern 200 may be formed on the same photoresist layer 650 that will be used to etch the interlayer dielectric layer 500 to form the slit type contact holes 501. The openings or contact hole patterns 651 of the photoresist layer 650 for formation of the contact holes 501 may be formed to have a shape substantially equal to the that of the contact holes 501. For example, the contact hole patterns 651 may have a slit shape crossing the gates 620. In this case, the contact hole patterns 651 have a shorter-axis dimension substantially equal to the shorter-axis dimension of the contact holes 501. The second vernier patterns 201 may have a dimension and a pitch substantially equal to those of the contact hole patterns 651.

Meanwhile, where the inner pattern 200 has the form of a single pattern having a size and a pitch substantially equal to those of the slit type contact holes 501, they are densely arranged to form a cluster having a square shape. In this case, detected light of a sufficient intensity can be obtained for the inner pattern 200. The peak of the detected light is compared with the peak of the detected light for the outer pattern 100 to measure the alignment. The spacing between the second vernier patterns 201 is set to a value sufficient for causing a reinforced interference between overlay measurement lights. This value may also be applied to the spacing between the adjacent first vernier patterns 101.

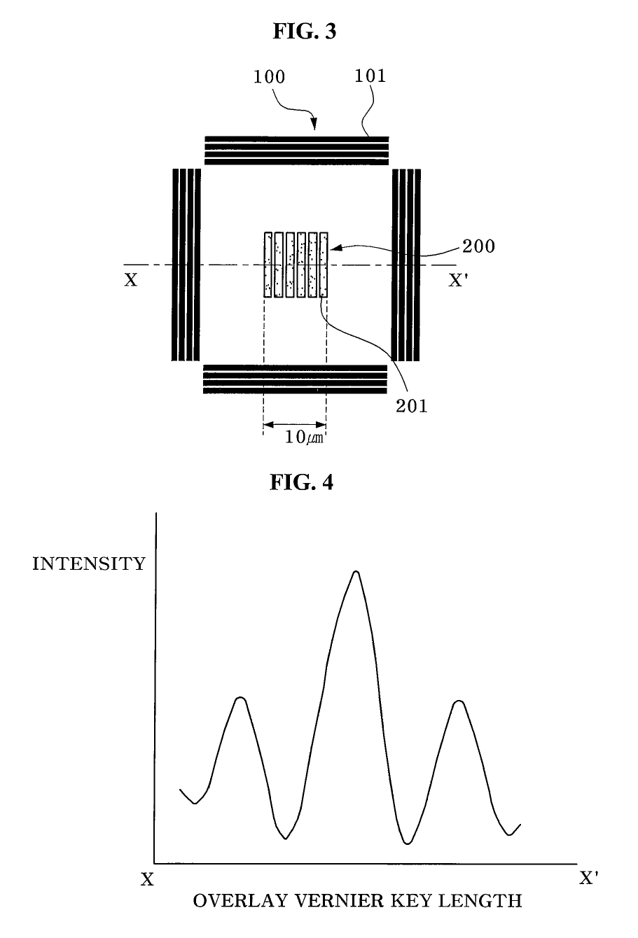

Since the inner pattern 200 is made up of the second vernier patterns 201 having a dimension and a pitch substantially equal to those of the slit type contact holes 501, the mask patterns on the photomask for each second vernier pattern 201 and each slit type contact hole 501 have the substantially same dimension and pitch. Accordingly, generation of an optical path deviation caused by lens aberrations, as shown in FIG. 2, can be compensated. Also, it is possible to eliminate an excess influence of the cell pattern caused by a size difference between the overlay vernier key structure and the cell pattern when a light exposure re-alignment is carried out for overlay adjustment after the overlay measurement.

Referring to FIGS. 6 and 7, the contact hole patterns 651 are formed in the photoresist layer 650 after accurate positions of the contact hole patterns 651 are determined through the overlay measurement. An etch process is then carried out on the interlayer dielectric layer 500, using the patterned photoresist layer 650 as an etch mask. As a result, the contact hole 501 is formed through the interlayer dielectric layer 500, as shown in FIG. 7 (***501 IS NOT SHOWN IN FIG. 7***). Thereafter, a connecting contact (or via plug) 661 and a conductive layer 660 such as a bit line layer or a metal line layer to be connected to the connecting contact 661 are formed to fill each contact hole 501. In accordance with the formation of the conductive layer 660 and contact 661, formation of a peripheral circuit in the peripheral region of the semiconductor substrate 610 is completed.

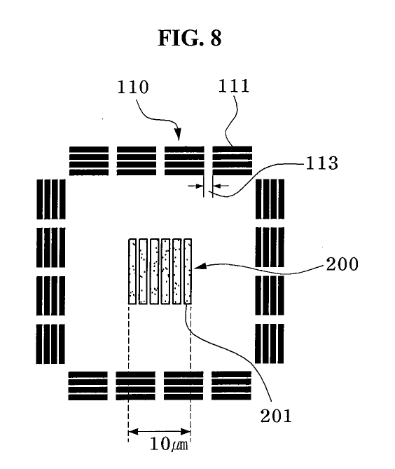

FIG. 8 is a plan view schematically illustrating a modified example of the overlay vernier key according to the illustrated embodiment of the present invention.

Referring to FIG. 8, the overlay vernier key structure according to the illustrated embodiment may be modified such that the outer pattern 110 includes third vernier patterns 111 repeatedly arranged in the form of line patterns along each side of the outer pattern 110 while having a length smaller than that of each side of the outer pattern. The spacing 113 of the third vernier patterns 111 in an extension direction of the associated side of the outer pattern 110 may be set to be substantially equal to a minimum design rule size, for example, a dimension of the gate 620 (FIG. 6). That is, it can be understood that the third vernier patterns 111, which have an elongated discrete pattern structure as shown in FIG. 8, is a modification of the first vernier patterns 101 (FIG. 3) having an elongated continuous pattern structure as shown in FIG. 3.

As apparent from the above description, the overlay vernier key structure according to the illustrated embodiment of the present invention can prevent a pattern misalignment, and can compensate the influence of lens aberrations in light exposure equipment. Accordingly, it is possible to prevent a misalignment of contact holes, and thus, to achieve a reduction in the contact resistance of a chip. An increase in the threshold voltage of a transistor can be achieved. Thus, a semiconductor chip having a high performance can be manufactured.

Although the embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A substrate including a first region and a second region, the substrate comprising:
a plurality of active patterns formed in the first region of the substrate; and
an overlay vernier key formed in the second region and including an outer pattern and an inner pattern, the inner pattern formed on an inner side of the outer pattern when seen from top,
wherein the outer pattern is formed over a first layer of the substrate, the outer pattern configured to be a reference for an overlay measurement, and
wherein the inner pattern is formed over a second layer of the substrate, the inner pattern comprising a cluster of first vernier patterns, each first vernier pattern having a dimension and a pitch equal to a dimension and a pitch of one of the active patterns formed on the first region.

2. The substrate of claim 1, wherein the one active pattern is a contact hole pattern that is formed to have a minimum design rule size according to a design rule for a device formed on the substrate, wherein the inner pattern is defined within an area defined by the outer pattern.

3. The substrate of claim 2, wherein the contact hole pattern is a slit-type contact hole pattern that is longer in a first direction than a second direction, wherein the dimension and the pitch of each first vernier pattern are substantially equal to a dimension and a pitch of the slit-type contact hole pattern in the first direction.

4. The substrate of claim 1, wherein the slit-type contact hole pattern is configured enable a bit line layer or a metal line layer formed over the second layer to a semiconductor material.

5. The substrate of claim 1, wherein the cluster has a square-like shape.

6. The substrate of claim 1, wherein the substrate is a semiconductor substrate, wherein the outer pattern comprises a plurality of second vernier patterns, each second vernier pattern having a dimension and a pitch equal to a dimension and a pitch of gates formed in the first region of the substrate.

7. The substrate of claim 6, wherein the second vernier patterns are grouped into a plurality of clusters that together define a square area.

8. The substrate of claim 7, wherein each second vernier pattern comprises a line pattern that has a line length corresponding to a length of one side of the square area.

9. The substrate of claim 7, wherein each second vernier pattern comprises a plurality of line patterns that are aligned and together have a length corresponding to a length of one side of the square area.

10. The substrate of claim 9, wherein the plurality of line patterns have a spacing substantially equal to a minimum design rule size according to a design rule for the substrate.

11. A method for forming contact holes in a semiconductor device, the method comprising:
forming gates and an outer pattern as a reference for an overlay measurement over a semiconductor substrate;
depositing an insulating layer covering the gates and the outer pattern;
forming a photoresist pattern including contact hole patterns and an inner pattern comprising a cluster of vernier patterns of a dimension and a pitch substantially equal to a dimension and a pitch of the contact hole patterns, over the insulating layer;
detecting a position of the inner pattern and a position of the outer pattern, to perform an overlay measurement; and
etching the insulating layer using the photoresist pattern as an etch mask to form contact holes through the interlayer insulating layer.

12. The method according to claim 11, wherein each contact hole pattern comprises a slit-type contact hole pattern that is longer in a first direction than a second direction, wherein the dimension and the pitch of each vernier pattern are substantially equal to a dimension and a pitch of the slit-type contact hole pattern in the second direction.

13. The method according to claim 11, wherein each slit-type contact hole pattern is arranged in a peripheral circuit region of the semiconductor substrate, to connect a bit line layer or a metal line layer formed on another insulating layer to the semiconductor substrate.

14. The method according to claim 11, wherein the outer pattern comprises a plurality of second vernier patterns having a dimension and a pitch equal to a dimension and a pitch of the gates formed on the semiconductor substrate, wherein the second vernier patterns are grouped into a plurality of clusters that together define a square-like area.

15. A substrate including a first region and a second region, the substrate comprising:
a plurality of active patterns formed in the first region of the substrate; and
an overlay vernier key formed in the second region and including a first cluster pattern including a plurality of first vernier patterns, each first vernier pattern having a dimension and a pitch substantially equal to a dimension and a pitch of a first pattern type of the active patterns formed on the first region.

16. The substrate of claim 15, wherein the overlay vernier key further comprises:
a second cluster pattern provided adjacent to the first cluster pattern and including a plurality of second vernier patterns, each second vernier pattern having a dimension and a pitch substantially equal to the dimension and a pitch of a second active type of the active patterns formed on the first region.

17. The substrate of claim 16, wherein the second cluster pattern defines an area wherein the first cluster pattern is provided within the defined area.

18. The substrate of claim 17, wherein the second cluster pattern includes two horizontal portions and two vertical portions, each of the horizontal and vertical portions including a plurality of patterns.
